(19) United States
(12) Patent Application Publication
(10) Pub. No.: US 2013/0328580 A1
(43) Pub. Date: Dec. 12, 2013

(54) TEST CIRCUIT FOR POWER SUPPLY UNIT

(71) Applicants: BO TIAN, Shenzhen City (CN); KANG WU, Shenzhen City (CN)

(72) Inventors: BO TIAN, Shenzhen City (CN); KANG WU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/564,760

(22) Filed: Aug. 2, 2012

(30) Foreign Application Priority Data
Jun. 8, 2012 (CN) 201210187437.1

(51) Int. Cl. G01R 27/08

(52) U.S. Cl. 324/713

(57) ABSTRACT

Atest circuit includes a test unit and a converting unit. The test unit includes a first connector connected to a power supply unit, a second connector connected to a motherboard, a sensing resistor, a controller, and an electronic switch. Two input pins of the controller are connected to two ends of the sensing resistor. A first terminal of the electronic switch is connected to the first connector through the sensing resistor. A second terminal of the electronic switch is connected to a control pin of the controller. A third terminal of the electronic switch is connected to the second connector. The converting unit includes a third connector connected to a monitoring device and a converter. Two input pins of the converter are connected to two output pins of the controller. Two data pins of the converter are connected to the third connector.

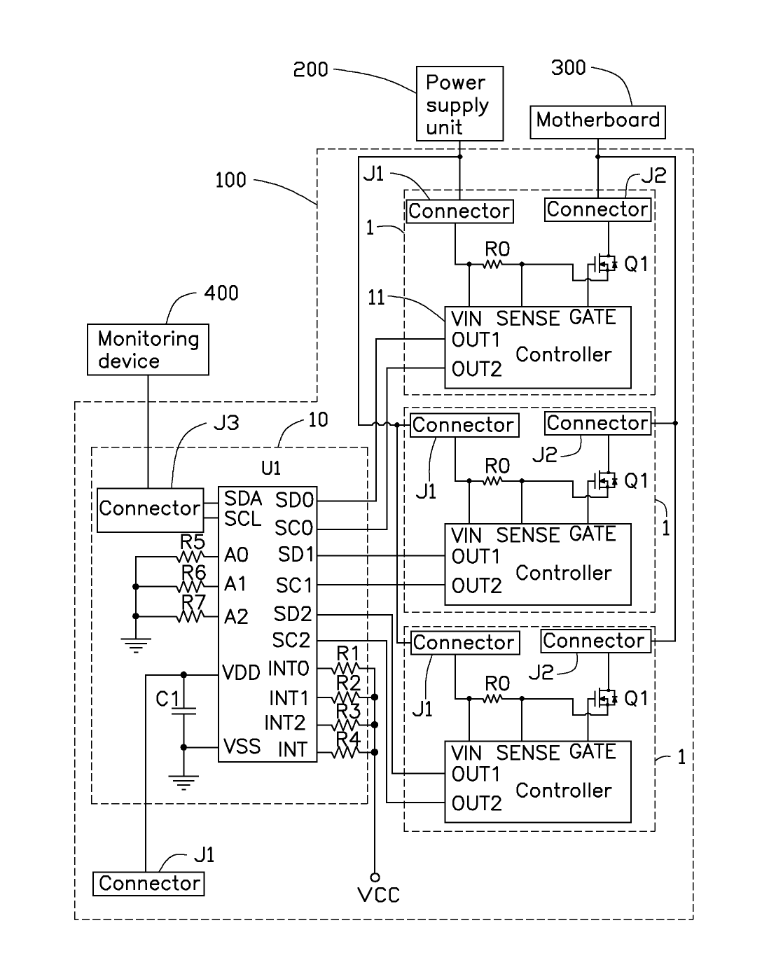

### BACKGROUND

1. Technical Field

The present disclosure relates to test circuits, and particularly to a testing circuit for testing a power supply unit.

2. Description of Related Art

At present, a power supply unit of an electronic device is designed for high converting efficiency, to save electrical energy. In this way, the power supply unit will not match with the motherboard of the electronic device, Thus resulting in the motherboard working abnormally. Therefore, there is room for improvement in the art.

### BRIEF DESCRIPTION OF THE DRAWING

Many aspects of the embodiments can be better understood with reference to the following drawing. The components in the drawing are not necessarily drawn to scale, the emphasis instead being placed upon clearly illustrating the principles of the present embodiments.

The FIGURE is a circuit diagram of a test circuit for a power supply unit in accordance with an exemplary embodiment of the present disclosure.

### DETAILED DESCRIPTION

The disclosure, including the drawing, is illustrated by way of example and not by way of limitation. References to “an” or “one” embodiment in this disclosure are not necessarily to the same embodiment, and such references mean at least one.

Referring to the figure, a testing circuit 100 is connected to a power supply unit 200 and a motherboard 300 of an electronic device. The testing circuit 100 in accordance with an exemplary embodiment includes at least one test unit 1 (three test units are shown) and at least one converting unit 10 (one converting unit is shown). Each test unit 1 includes connectors J1 and J2, a sensing resistor RO, a controller 11, an electronic switch, such as an n-channel field effect transistor (FET) Ql. The connector J1 is connected to the power supply unit 200, to receive an output voltage from the power supply unit 200. The connector J2 is connected to the motherboard 300, to transmit the output voltage from the power supply unit 200 to the motherboard 300. Each converting unit 10 includes a converter U1, resistors R1-R7, a capacitor C1, and a connector J3. The connector J3 is connected to a monitoring device 400, which displays test information. The output voltages of the power supply unit 200 are 12 volts (V), 3.3V, and 5V. In other embodiments, the number of the test unit 1 is equal to the number of the output voltages of the power supply unit 200.

A gate of the FET Q1 is connected to a control pin GATE of the controller 11. A source of the FET Q1 is connected to the connector J1 through the sensing resistor RO. A drain of the FET Q1 is connected to the connector J2. Two input pins VIN and SENSE of the controller 11 are respectively connected to two ends of the sensing resistor R0. Two input pins SD0 and SC0, two input pins SD1 and SC1, and two input pins SD2 and SC2 of the converter U1 are respectively connected to two output pins OUT1 and OUT2 of the controllers 11 of the three test units 1. Interrupt pins INT0, INT1, INT2, and INT of the converter U1 are connected to a power source VCC respectively through resistors R1-R4. A voltage pin VDD of the converter U1 is connected to the connector J1 and also grounded through the capacitor C1. Input output (I/O) pins A0-A2 of the converter U1 are grounded respectively through resistors R5-R7. Data pins SDA and SCL of the converter U1 are connected to the connector J3.

In use, the power supply unit 200 and the motherboard 300 are powered on. An output voltage, such as 5V, of the power supply unit 200 is provided to the sensing resistor RO through the connector J1. The controller 11 gains the voltage of the sensing resistor RO through the input pins VIN and SENSE, converts the voltage to a current, and outputs the current to the converter U1. The converter U1 converts the current to system management bus (SMBUS) signals and outputs the SMBUS signals to the monitoring device 400 through the connector J3. Loads of the motherboard 300 can be regulated according to the testing information displayed on the monitoring device 400, to match the motherboard 300 with the power supply unit 200. At the same time, the controller 11 outputs a control signal, such as a high level signal, through the control pin GATE to control the FET Q1 to be turned on, to provide the 5V of the power supply unit 200 to the motherboard 300 through the connector J2. Other test units 1 are used for testing other output voltages, such as 12 V and 3.3 V, of the power supply unit 200, theories are the same as the above theory.

In brief, the testing circuit 100 converts the output voltage of the power supply unit 200 to a current and converts the current to SMBUS signals, to be displayed through the monitoring device 400. The loads of the motherboard 300 can be regulated according to the testing information displayed by the monitoring device 400, to match the motherboard 300 with the power supply unit 200.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A test circuit applicable to test a power supply unit, the test circuit comprising:
at least one test unit each comprising:
a first connector connected to the power supply unit for receiving an output voltage from the power supply unit;
a second connector connected to a motherboard for providing the output voltage of the power supply to the motherboard;
a sensing resistor;
a controller comprising two input pins connected to two ends of the sensing resistor, a control pin, and two output pins; and
an electronic switch comprising a first terminal connected to the first connector through the sensing resistor, a second terminal connected to the control pin of the controller, and a third terminal connected to the second connector; and
at least one converting unit each comprising:
a third connector connected to a monitoring device; and
a converter comprising two input pins connected to the output pins of the controller, and two data pins connected to the third connector;
wherein the controller gains a voltage of the sensing resistor through the input pins of the controller, converts the voltage to a current, and provides the current to the converter, the converter converts the current to system management bus (SMBUS) signals and outputs the SMBUS signals to the monitoring device through the third connector, the controller outputs a control signal through the control pin to control the electronic switch to be turned on, to provide the output voltage of the power supply unit to the motherboard.

2. The test circuit of claim 1, wherein the converting unit further comprises first to seventh resistors and a capacitor, first to fourth interrupt pins of the converter are connected to a power source respectively through the first to fourth resistors, a voltage pin of the converter is connected to the first connector and also grounded through the capacitor, first to third input output (I/O) pins of the converter are grounded respectively through the fifth to seventh resistors.

3. The test circuit of claim 1, wherein the electronic switch is an n-channel field effect transistor (FET), the first to third terminals of the electronic switch are respectively a source, a gate, and a drain of the FET.
